(19) United States
(12) Patent Application Publication
(10) Pub. No.: US 2023/0422542 A1
(43) Pub. Date: Dec. 28, 2023

(54) OLED DISPLAY PANEL AND FABRICATION METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Jingyuan Hu, Shenzhen (CN); Fanjing Wu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/816,407

(22) Filed: Jul. 30, 2022

(30) Foreign Application Priority Data
Jun. 28, 2022 (CN) 202210750640.9

(51) Int. Cl. H01L 51/52; H01L 27/32; H01L 51/56

(52) U.S. Cl. CPC H01L 51/5228; H01L 27/3248; H01L 27/3258; H01L 27/3272; H01L 27/3276; H01L 51/5218; H01L 51/56; H01L 2227/323

(57) ABSTRACT

An embodiment of the present invention discloses an OLED display panel and a fabrication method thereof. The OLED display panel includes an array substrate with an auxiliary electrode layer on the array substrate; an anode layer is disposed on the array substrate, and the anode layer has an undercut opening, and the auxiliary electrode layer is exposed in the undercut opening; the light-emitting layer is provided on the anode layer and a portion thereof in the undercut opening is disconnected, covering a portion of the auxiliary electrode layer in the undercut opening; a cathode layer disposed on the light emitting layer and covers a portion of the auxiliary electrode layer in the undercut opening. By setting an undercut opening in the anode layer and connecting the cathode with the auxiliary electrode through the undercut opening, the problem of IR-drop can be improved.

### FIELD OF INVENTION

The invention relates to the field of display panels, and particularly to an OLED display panel and a fabrication method thereof.

### BACKGROUND

An OLED display panel structure comprises a transparent anode, a light-emitting layer and a metal cathode. In order to increase the transmittance of top emission, a thickness of the metal cathode is relatively thin, causing large square resistances and serious current drops (IR-drop) and resulting in obvious uneven brightness of the display panel, which seriously affects an OLED display device. display effect. In order to improve the non-uniformity of the display brightness of the panel, an auxiliary electrode can be set up and connected with a thinner metal cathode. Since a resistance of the auxiliary electrode is small, the current voltage drop is reduced, and the impedance and current voltage drop of the cathode of the panel are reduced when the power is turned on, and the brightness uniformity is improved to a certain extent. For how to realize the overlap between the auxiliary electrode and the metal cathode, an inverted trapezoidal isolation column is usually provided between the cathode and the auxiliary electrode, but the volume of the isolation column is large, which affects an aperture ratio and packaging. The selectivity of raw materials is less, making the process becomes complicated and the production efficiency is reduced.

In view of this, it is necessary to develop a new type of OLED display panel to solve the problem of complicated fabrication process due to the need to prepare spacers in order to improve IR-drop in the prior art.

### TECHNICAL SOLUTION

Embodiments of the present invention provide an OLED display panel and a fabrication method of fabricating the same, so as to solve the problem in the prior art that isolation columns need to be provided in order to improve IR-drops, which leads to complicated fabrication processes.

In order to solve the above technical problems, embodiments of the present invention disclose the following technical solutions:

In one aspect, the present application provides an OLED display panel, comprising an array substrate, having an auxiliary electrode layer fabricated on the array substrate; an anode layer disposed on the array substrate, wherein along a vertical direction that the anode layer comprises a first electrode layer disposed on the array substrate; a reflective layer disposed on the first electrode layer; a third electrode layer disposed on the reflective layer; an undercut opening penetrating the first electrode layer, wherein the auxiliary electrode is exposed in the undercut opening; and a through hole penetrating the reflective layer and the third electrode layer, wherein the undercut opening connects the through hole, and a projection of the through hole on the substrate falls into a projection of the undercut opening on the substrate; a light-emitting layer disposed on the anode layer and being partially disconnected in the undercut opening, covering a portion of the auxiliary electrode layer in the undercut opening; and a cathode layer disposed on the light-emitting layer, covering a portion of the auxiliary electrode layer in the undercut opening.

In addition to or as an alternative to one or more of the features disclosed above, the array substrate comprises a substrate; a buffer layer disposed on the substrate; an active layer disposed on the buffer layer; a gate insulating layer disposed on the active layer; a gate layer disposed on the gate insulating layer; an interlayer dielectric layer disposed on the gate layer; a metal layer disposed on the interlayer dielectric layer, wherein the metal layer comprises a plurality of source-drain layers and an auxiliary electrode layer arranged at intervals in the same layer, and the plurality of source-drain layers are connected to the active layer; a passivation layer disposed on the auxiliary electrode and the plurality of source-drain layers; a planarization layer disposed on the passivation layer; a first via hole penetrating the planarization layer and the passivation layer from a side of the planarization layer away from the substrate, and the plurality of source-drain layers are exposed in the first via hole; and a second via hole penetrating the planarization layer and the passivation layer from the side of the planarization layer away from the substrate, and is spaced apart from the first via hole, and the auxiliary electrode layer is exposed in the fie via hole.

In addition to or as an alternative to one or more of the features disclosed above, the anode layer comprises a first anode layer and a second anode layer arranged at intervals in the same layer; the first anode layer is disposed on the planarization layer and connected to the source-drain through the first via hole; and the second anode layer is disposed on the planarization layer and covers sidewalls of the second via hole, the second anode layer has the undercut opening, and the auxiliary electrode layer is exposed in the undercut opening.

In addition to or as an alternative to one or more of the features disclosed above, the reflective layer and the third electrode layer comprise a plurality of protrusion portions protruding inward from the sidewalls of the second via hole.

In addition to or as an alternative to one or more of the features disclosed above, the cathode layer is continuously disposed on the light-emitting layer and the plurality of protruding portions.

In addition to or as an alternative to one or more of the features disclosed above, the metal layer further comprises a pad layer spaced apart from the plurality of source-drain layers and the auxiliary electrode layer, and an area along a vertical direction of the pad layer is defined as a bonding area.

In another aspect, the present application provides a fabrication method of an OLED display panel, comprising providing an array substrate, wherein the array substrate comprises an auxiliary electrode thereon; and fabricating an anode layer on the array substrate, wherein the step of fabricating the anode layer specifically comprises fabricating a first electrode layer on the array substrate; fabricating a reflective layer on the first electrode layer, fabricating a third electrode layer on the reflective layer; fabricating a through hole, wherein the through hole penetrates the first electrode layer and the third electrode layer from a side of the third electrode layer away from the array substrate and extends to a side of the auxiliary electrode away from the array substrate; fabricating an undercut opening on the first electrode layer, wherein the undercut opening connects the through hole, and the auxiliary electrode is exposed in the undercut opening, wherein a projection of the through hole on the array substrate falls into a projection of the undercut opening on the array substrate; fabricating a light-emitting layer on the anode layer, wherein the light-emitting layer is partially disconnected in the undercut opening, and the light-emitting layer covering a portion of the auxiliary electrode layer in the undercut opening; and fabricating a cathode layer on the light-emitting layer and covering a portion of the auxiliary electrode layer in the undercut opening.

In addition to or as an alternative to one or more of the features disclosed above, a material of the first electrode layer is an indium zinc oxide film, a material of the reflective layer is one or more of molybdenum, titanium, silver alloy, aluminum alloy or molybdenum titanium alloys, and a material of the third electrode is indium tin oxide film.

In addition to or as an alternative to one or more of the features disclosed above, the anode layer is etched by a wet etching process to form the through hole, and the first electrode is etched by an oxalic acid to form the undercut opening.

In addition to or as an alternative to one or more of the features disclosed above, the step of fabricating the light-emitting layer and the cathode layer comprise controlling a vapor deposition angle of a vapor deposition source at a first set angle and forming the light-emitting layer on the anode layer by a vapor deposition, wherein the light-emitting layer is disconnected in the undercut opening, and there is a gap is formed between the light-emitting layer on the auxiliary electrode layer and the light-emitting layer on the anode layer; and adjusting the vapor deposition angle of the vapor deposition source to a second set angle, forming the cathode layer on the light-emitting layer by the vapor deposition and covering a portion of the auxiliary electrode layer in the undercut opening, wherein the cathode layer and the exposed auxiliary electrode layers are in contact with each other.

One of the above technical solutions has the following advantages or beneficial effects:

By fabricating an undercut opening in the anode, the cathode is connected to the auxiliary electrode through the undercut opening to improve the problem of IR-drops. The anode comprises a first electrode layer, a reflective film layer and a third electrode layer. The first electrode layer is formed of indium zinc oxide film, the reflective film layer is formed of metal, the third electrode layer is formed of indium tin oxide film, and the first electrode layer is etched with an oxalic acid to form an undercut opening, the fabrication process is simple, and the production efficiency can be improved.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic structural diagram of an OLED display panel provided by an embodiment of the present invention.

FIG. 2 is a flowchart of a fabrication method of an OLED display panel provided by an embodiment of the present invention.

FIG. 3 is a schematic structural diagram of a step 1 of the fabrication method of the OLED display panel provided by an embodiment of the present invention.

FIG. 4 is a schematic structural diagram of a step 2 of the fabrication method of the OLED display panel according to an embodiment of the present invention.

FIG. 5 is a schematic structural diagram of a step 21 of the fabrication method of the OLED display panel according to an embodiment of the present invention.

FIG. 6 is a schematic structural diagram of a step 3 of the fabrication method of the OLED display panel according to an embodiment of the present invention.

FIG. 7 is a schematic structural diagram of a step 4 of the fabrication method of the OLED display panel provided by an embodiment of the present invention.

FIG. 8 is a schematic structural diagram of a step 5 of the fabrication method of the OLED display panel according to an embodiment of the present invention.

### DETAILED DESCRIPTION

Technical solutions in the embodiments of the present invention will be clearly and completely described below with reference to the accompanying drawings in the embodiments of the present invention. In the description of the present invention, it should be understood that the terms “center”, “longitudinal”, “lateral”, “length”, “width”, “thickness”, “upper”, “lower”, “front”, “rear, left, right, vertical, horizontal, top, bottom, inside, outside, clockwise, counterclockwise, etc., or The positional relationship is based on the orientation or positional relationship shown in the accompanying drawings, which is only for the convenience of describing the present invention and simplifying the description, rather than indicating or implying that the referred device or element must have a specific orientation, be constructed and operated in a specific orientation, Therefore, it should not be construed as a limitation of the present invention.

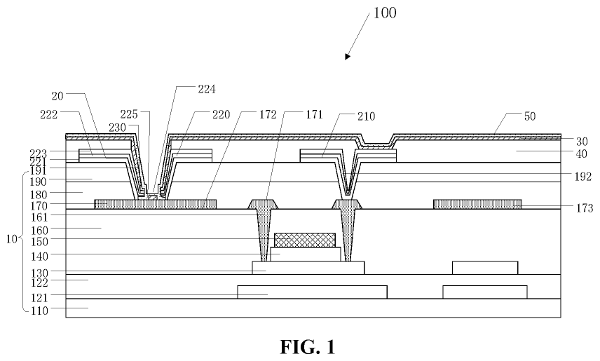

Please refer to FIG. 1, which is a schematic structural diagram of an OLED display panel 100 provided in the present embodiment. The OLED display panel 100 comprises an array substrate 10, an anode layer 20, a light-emitting layer 30, a pixel definition layer 40 and a cathode layer 50.

The array substrate 10 comprises a substrate 110, a light shielding layer 121, a buffer layer 122, an active layer 130, a gate insulating layer 140, a gate layer 150, an interlayer dielectric layer 160, a metal layer 170, a passivation layer 180, a planarization layer 190, a plurality of contact holes 161, a first via hole 191 and a second via hole 192. A material used for the substrate 110 may be a polymer resin, such as polyethersulfone (PES), polyacrylate (PAR), polyetherimide (PEI), polyethylene naphthalate (PEN), polyethylene terephthalate Ethylene formate (PET), polyphenylene sulfide (PPS), polyarylate, polyimide (PI), polycarbonate (PC) or cellulose acetate propionate (CAP). The light shielding layer 121 is disposed on the substrate 110, and the buffer layer 122 is disposed on the light shielding layer 121.

The active layer 130 is disposed on the buffer layer 122, and the gate insulating layer 140 is disposed on the active layer 130. The gate insulating layer 140 comprises an inorganic layer such as silicon oxide, silicon nitride, and may comprise a single layer or multiple layers. The gate layer 150 is disposed on the gate insulating layer 140, and the interlayer dielectric layer 160 is disposed on the gate layer 150. The interlayer dielectric layer 160 may comprise an inorganic material or an organic material. The inorganic material may be at least one selected from silicon nitride, aluminum nitride, zirconium nitride, titanium nitride, hafnium nitride, tantalum nitride, silicon oxide, aluminum oxide, titanium oxide, tin oxide, ceria, and silicon oxynitride. The organic material may be at least one selected from acrylic resins, methacrylic resins, polyisoprene, vinyl-based resins, epoxy-based resins, urethane-based resins, cellulose-based resins, and perylene-based resins.

The metal layer 170 is disposed on the interlayer dielectric layer 160. The metal layer 170 comprises a plurality of source-drain layers 171, an auxiliary electrode layer 172 and a pad layer 173 arranged at intervals in the same layer. A material of the source-drain layers 171 and the auxiliary electrode layer 172 may be any one or more of silver, molybdenum, aluminum, and copper. Along a vertical direction where an area of the pad layer 173 located is a bonding area.

The contact holes 161 extend from a surface of the interlayer dielectric layer 160 away from the substrate 110 to a surface of the active layer 130 away from the substrate 110. The source-drain layers 171 are connected to the active layer 130 through the contact holes 161. The passivation layer 180 is disposed on the auxiliary electrode and the source-drain layers 171.

The planarization layer 190 is disposed on the passivation layer 180. The planarization layer 190 may comprise an organic material such as acrylic, polyimide (PI) or benzocyclobutene (BCB). The planarization layer 190 has a planarization function. The first via hole 191 penetrates the planarization layer 190 and the passivation layer 180 from a surface of the planarization layer 190 away from the substrate 110, and the auxiliary electrode layer 172 is exposed in the first via hole 191. The second via hole 192 penetrates the planarization layer 190 and the passivation layer 180 from the surface of the planarization layer 190 away from the substrate 110, and one of the source-drain layers 171 is exposed in the second via hole 192.

The anode layer 20 comprises a first anode layer 210 and a second anode layer 220 arranged at intervals in the same layer. The first anode layer 210 is disposed on the planarization layer 190 and in the first via hole 191, and the first anode layer 210 is connected to the source-drain through the first via hole 191. The second anode layer 220 is disposed on the planarization layer and in the second via hole 192, and the second anode layer 220 is connected to the auxiliary electrode layer 172 through the second via hole 192.

The first anode layer 210 comprises a first electrode layer 221, a reflective layer 222 and a third electrode layer 223 that are stacked.

The second anode layer 220 comprises a first electrode layer 221, a reflective layer 222, a third electrode layer 223, a through hole 224, and an undercut opening 225 that are stacked. The first electrode layer 221 is disposed on the planarization layer 190 and covers sidewalls of the second via hole 192. The undercut opening 225 penetrates the first electrode layer 221, and the auxiliary electrode layer 172 is exposed in the undercut opening 225. The reflective layer 222 is disposed on the first electrode layer 221. The third electrode layer 223 is disposed on the reflective layer 222. The through hole 224 penetrates the reflective layer 222 and the third electrode layer 223, and the undercut opening 225 connects the through hole 224. The reflective layer 222 and the third electrode layer 223 comprises a plurality of protruding portions 230 protruding inward from sidewalls of the first via hole 191.

A material of the first electrode layer 221 can be an indium zinc oxide film. A material of the reflective layer 222 can be one or more of molybdenum, titanium, silver alloy, aluminum alloy or molybdenum-titanium alloy. A material of the third electrode layer 223 can be an indium tin oxide film.

The pixel definition layer 40 is disposed on the planarization layer 190 and the anode layer 20. The light emitting layer 30 is disposed on the pixel definition layer 40 and the anode layer 20 and is partially disconnected in the undercut opening 225 and covers a portion of the auxiliary electrode layer 172 in the undercut opening 225. There is a gap formed between the light emitting layer 30 on the auxiliary electrode layer 172 and the light emitting layer 30 on the anode layer 20. The light emitting layer is formed by an evaporation deposition and is disconnected at the undercut opening due to the existence of the undercut opening.

Specifically, the light-emitting layer 30 comprises film layers such as a hole injection layer, a hole transport layer, an organic light-emitting layer, an electron injection layer, and an electron transport layer that are stacked in sequence. The light-emitting layer at least comprises a red light-emitting layer, a green light-emitting layer, and a blue light-emitting layers.

The cathode layer 50 is continuously disposed on the light-emitting layer 30 and the protruding portions 230 and covers portions of the auxiliary electrode layer 172 in the undercut opening 225. The cathode layer 50 connects the auxiliary electrode layer 172 through the undercut opening 225, so that the cathode layer 50 and the auxiliary electrode together form a parallel structure, thereby reducing the cathode resistance and achieving the effect of improving the current and voltage drop of the OLED display panel 100, which is beneficial to improve a brightness uniformity of the OLED display panel 100.

Due to the existence of the undercut opening, the subsequent light-emitting layer 30 is disconnected at the undercut opening 225, which avoids the continuity of the light-emitting layer 30, so that the light-emitting layer 30 does not cover the portion of the auxiliary electrode exposed by the gap. A portion of the auxiliary electrode layer 172 overlapping with the cathode layer 50 is further reserved, so that the cathode layer 50 covers the portion of the auxiliary electrode layer 172 not covered by the light-emitting layer 30 to realize the overlapping of the cathode layer 50 and the auxiliary electrode layer 172.

In an embodiment of the present invention, a thickness of the auxiliary electrode layer 172 is greater than a thickness of the cathode layer 50. That is, a cross-section area of the auxiliary electrode layer 172 is greater than a cross-section area of the cathode layer 50. Since a resistance of the metal is negatively correlated with its cross-section area, a resistance of the auxiliary electrode layer 172 is less than a resistance of the cathode layer 50. Since the resistance of the parallel structure formed by the two metal layers is less than the resistance of any one of the metal layers, the resistance of the parallel structure formed by the cathode layer 50 and the auxiliary electrode layer 172 is less than the resistance of the auxiliary electrode layer 172, thereby greatly reducing the cathode resistance of the OLED display panel 100 and improving the effect of the current and voltage drop of the OLED display panel 100.

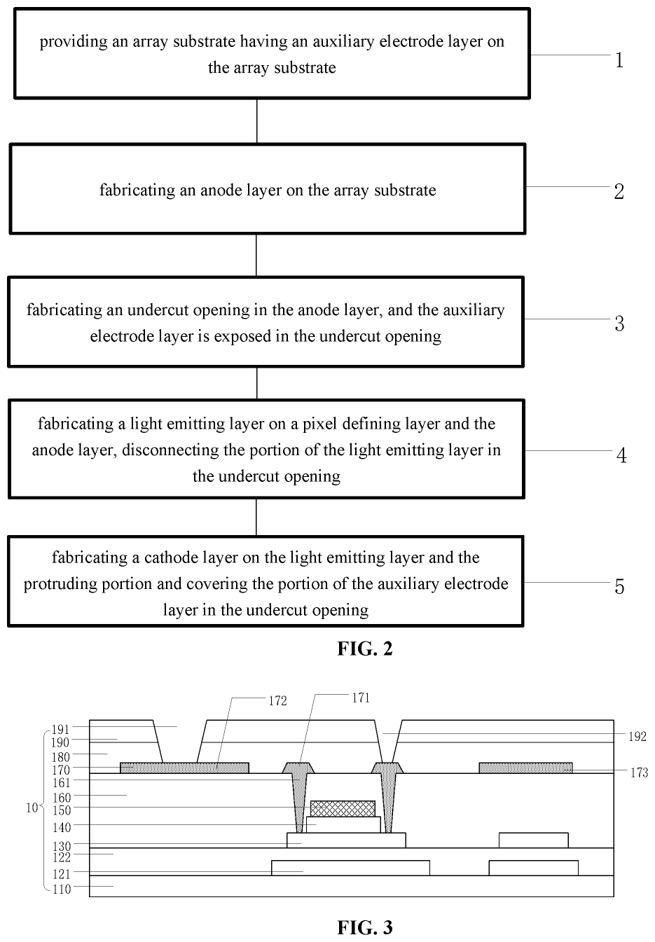

An embodiment of the present invention further provides a fabrication method of the OLED display panel 100 in the present invention. Please refer to FIG. 2, FIG. 2 is a flowchart of a fabrication method of the OLED display panel 100. The fabrication method comprises steps 1-4.

Step 1: fabricating an array substrate 10 having an auxiliary electrode layer 172 on the array substrate 10.

Please refer to FIG. 3, which is a schematic structural diagram of the step 1 of the fabrication method.

Specifically, the fabrication method comprises following steps.

A substrate 110 is provided, and a material of the substrate 110 can be a polymer resin such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC) or cellulose acetate propionate (CAP).

A light shielding layer 121 is fabricated on the substrate 110, and a buffer layer 122 is fabricated on the light shielding layer 121.

An active layer 130 is fabricated on the buffer layer 122, and a gate insulating layer 140 is fabricated on the active layer 130. The gate insulating layer 140 comprises an inorganic layer such as silicon oxide, silicon nitride, and it may comprise a single layer or multiple layers.

A gate layer 150 is fabricated on the gate insulating layer 140, and an interlayer dielectric layer 160 is fabricated on the gate layer 150. The interlayer dielectric layer 160 may comprise an inorganic material or an organic material. The inorganic material may comprise at least one selected from silicon nitride, aluminum nitride, zirconium nitride, titanium nitride, hafnium nitride, tantalum nitride, silicon oxide, aluminum oxide, titanium oxide, tin oxide, ceria, and silicon oxynitride. The organic material may comprise at least one selected from acrylic resins, methacrylic resins, polyisoprene, vinyl-based resins, epoxy-based resins, urethane-based resins, cellulose-based resins, and perylene-based resins.

A metal layer 170 is fabricated on the interlayer dielectric layer 160, and the metal layer 170 comprises a plurality source-drain layers 171, an auxiliary electrode layer 172 and a pad layer 173 arranged at intervals in the same layer. A material of the source-drain layers 171 and the auxiliary electrode layer 172 may be any one or more of silver, molybdenum, aluminum, and copper. Along a vertical direction, an area where the pad layer 173 located is defined as a bonding area.

A plurality of contact holes 161 are fabricated, and the contact holes 161 extend from a side of the interlayer dielectric layer 160 away from the substrate 110 to a surface of the active layer 130 away from the substrate 110, and the source-drain layers 171 are connected to the active layer 130 through the contact holes 161.

A passivation layer 180 is fabricated on the auxiliary electrode and the source-drain layers 171, and a planarization layer 190 is fabricated on the passivation layer 180. The planarization layer 190 may comprise acrylic, polyimide (PI) or benzocyclobutene (BCB) and other organic materials, the planarization layer 190 has a planarization effect.

A first via hole 191 and a second via hole 192 are fabricated, the second via hole 192 penetrates the planarization layer 190 and the passivation layer 180 from a side of the planarization layer 190 away from the substrate 110, and the source-drain layers 171 are exposed in the second via hole 192. The first via hole 191 penetrates the planarization layer 190 and the passivation layer 180 from the surface of the planarization layer 190 away from the substrate 110, and the auxiliary electrode layer 172 is exposed in the first via hole 191.

Step 2: fabricating the anode layer 20 on the array substrate 10.

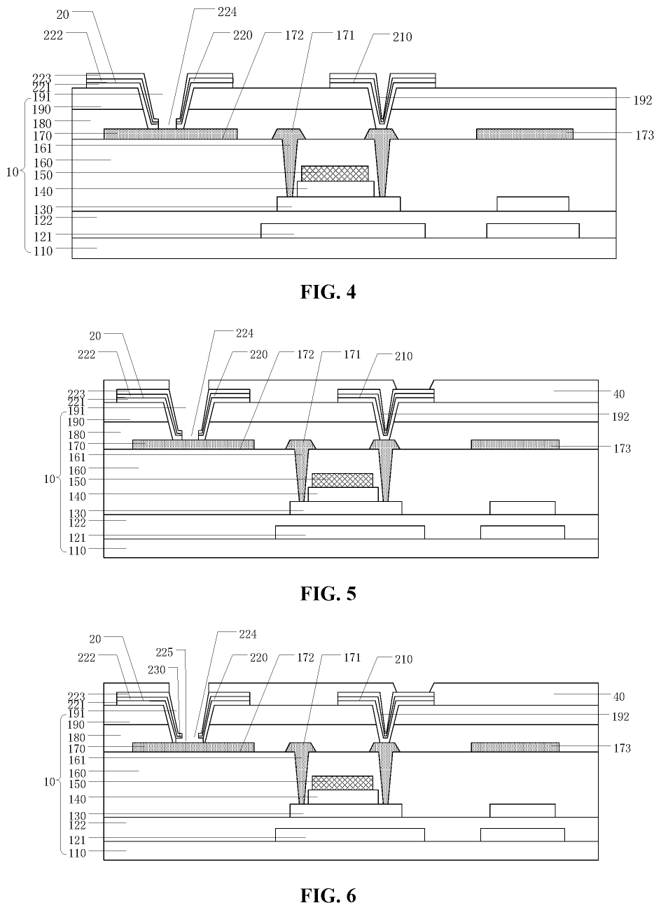

Please refer to FIG. 4, which is a schematic structural diagram of the step 2 of the fabrication method.

Specifically, the fabrication method comprises following steps.

A first anode layer 210 is fabricated on the planarization layer 190 and in the first via hole 191, and a second anode layer 220 is fabricated on the planarization layer 190 and in the second via hole 192. The first anode layer 210 and the second anode layer 220 are arranged at intervals in the same layer, the first anode layer 210 is connected to the source-drain electrodes through the first via holes 191, and the second anode layer 220 is connected to the auxiliary electrode layer 172 through the second via holes 192.

The steps of fabricating the first anode layer 210 specifically comprises:

A first electrode layer 221 is fabricated on the planarization layer 190 and covers the sidewalls of the first via hole 191. A material of the first electrode layer 221 may be an indium zinc oxide (IZO) film.

A reflective layer 222 is fabricated on the first electrode layer 221, and a material of the reflective layer 222 may be one or more of molybdenum, titanium, silver alloy, aluminum alloy or molybdenum-titanium alloy.

A third electrode layer 223 is fabricated on the reflective layer 222, and a material of the third electrode layer 223 may be an indium tin oxide (ITO) film.

The steps of fabricating the second anode layer 220 are specifically described as below.

The first electrode layer 221 is fabricated on the planarization layer 190 and covers the sidewalls of the second via hole 192. The material of the first electrode layer 221 may be an indium zinc oxide (IZO) film.

The reflective layer 222 is fabricated on the first electrode layer 221, and the material of the reflective layer 222 is one or more of molybdenum, titanium, silver alloy, aluminum alloy or molybdenum-titanium alloy.

The third electrode layer 223 is fabricated on the reflective layer 222, and the material of the third electrode layer 223 is an indium tin oxide (ITO)film.

A through hole 224 is fabricated, and the second anode layer 220 is etched by a wet etching process to form the through hole 224. The through hole 224 penetrates the second anode layer 220, and the through hole 224 penetrates the first electrode layer 221, the reflective layer 222 and the third electrode layer 223 from a side of the third electrode layer 223 away from the substrate 110 and extends to the surface of the auxiliary electrode layer 172 away from the substrate 110. The auxiliary electrode layer 172 is exposed in the through holes 224.

The fabrication method further comprises a step 21: fabricating the pixel defining layer 40 on the first anode layer 210 and the second anode layer 220.

Please refer to FIG. 5, which is a schematic structural diagram of a step 21 of the fabrication method.

After the pixel definition layer 40 is fabricated, the OLED display panel 100 is baked at a high temperature.

Step 3: fabricating an undercut opening 225 in the anode layer 20, and the auxiliary electrode layer 172 is exposed in the undercut opening 225.

Please refer to FIG. 6, which is a schematic structural diagram of a step 3 of the fabrication method.

The first electrode layer 221 is etched by an oxalic acid to form the undercut opening 225. The undercut opening 225 connects the through hole 224. The reflective layer 222 and the third electrode layer 223 comprises a plurality of protrusion portions 230 protruding inward from sidewalls of the first via holes 191.

The indium tin oxide film will be crystallized and degenerated after the high temperature baking, and the indium tin oxide film will be crystallized, which is difficult to be etched. Etching performances of the oxalic acid is thus limited, and the crystallized ITO cannot be etched. The indium zinc oxide film is an amorphous material because of its material characteristics. High temperature cannot make its atoms rearrange and cannot be crystallized, so the oxalic acid can etch the first electrode layer 221.

Step 4: fabricating the light emitting layer 30 on the pixel defining layer 40 and the anode layer 20 and disconnecting the portion of the light emitting layer 30 in the undercut opening 225.

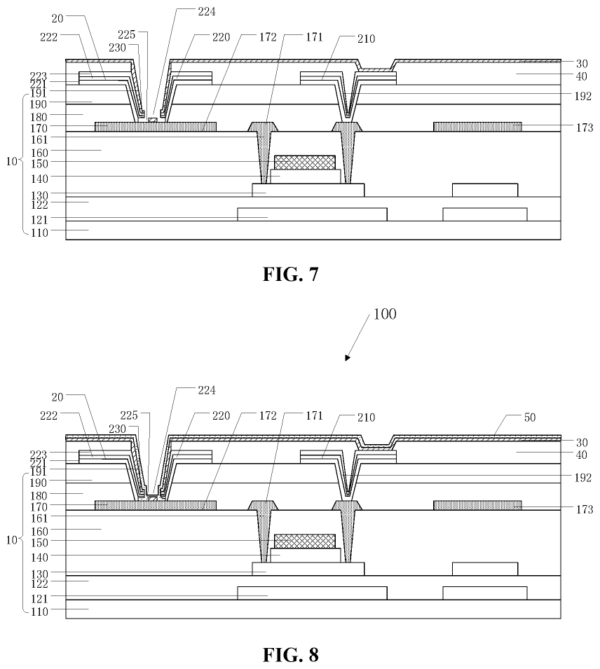

Please refer to FIG. 7, which is a schematic structural diagram of the step 4 of the fabrication method.

A vapor deposition angle of a vapor deposition source is controlled to be a first set angle, and the light-emitting layer 30 is fabricated on the pixel definition layer 40 and the anode layer 20 by a vapor-deposition, and the portion of the light-emitting layer 30 in the undercut opening 225 is disconnected and covers the auxiliary electrode layer 172 in the undercut opening 225. A gap is formed between the light emitting layer 30 on the auxiliary electrode layer 172 and the light emitting layer 30 on the anode layer 20.

Due to the existence of the undercut opening, the light emitting layer 30 is disconnected in the undercut opening 225, thereby avoiding a continuity of the light emitting layer 30, so that the light emitting layer 30 does not cover the portion of the auxiliary electrode layer 172 exposed by the gap. Furthermore, the auxiliary electrode layer 172 reserves a portion overlapping the cathode layer 50.

Step 5: fabricating the cathode layer 50 on the light emitting layer 30 and the protruding portions 230 and covering a portion of the auxiliary electrode layer 17 in the undercut opening 225.

Please refer to FIG. 8, which is a schematic structural diagram of the step 5 of the fabrication method.

A vapor deposition angle of the vapor deposition source is adjusted to be the second set angle, and the vapor deposition cathode layer 50 is continuously disposed on the light emitting layer 30 and the protruding portions 230 and covers a portion of the auxiliary electrode layer 172 in the undercut opening 225 to realize overlapping of the cathode layer 50 with auxiliary electrode layer 172.

In other embodiments, the cathode layer 50 may also be fabricated by a sputtering process.

Using the principle that the crystalized material will not be etched by the oxalic acid, and the amorphous material can be easily etched by the oxalic acid, the material used in the first electrode layer 221 cannot be crystallized after being baked at a high temperature, and the material used in the third electrode layer 223 is baked at a high temperature. When it is crystallized, the first electrode layer 221 is etched by the oxalic acid to form an undercut opening 225, the fabrication process is simple, and the production efficiency can be improved.

The OLED display panel and the fabrication method thereof provided by the embodiments of the present invention are described in detail above. While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An OLED display panel, comprising:
an array substrate, having an auxiliary electrode layer fabricated on the array substrate;
an anode layer disposed on the array substrate, wherein along a vertical direction that the anode layer comprises:
a first electrode layer disposed on the array substrate;
a reflective layer disposed on the first electrode layer;
a third electrode layer disposed on the reflective layer;
an undercut opening penetrating the first electrode layer, wherein the auxiliary electrode is exposed in the undercut opening; and
a through hole penetrating the reflective layer and the third electrode layer, wherein the undercut opening connects the through hole, and a projection of the through hole on the substrate falls into a projection of the undercut opening on the substrate;
a light-emitting layer disposed on the anode layer and being partially disconnected in the undercut opening, covering a portion of the auxiliary electrode layer in the undercut opening; and
a cathode layer disposed on the light-emitting layer, covering a portion of the auxiliary electrode layer in the undercut opening.

2. The OLED display panel of claim 1, wherein the array substrate comprises:
a substrate;
a buffer layer disposed on the substrate;
an active layer disposed on the buffer layer;
a gate insulating layer disposed on the active layer;
a gate layer disposed on the gate insulating layer;
an interlayer dielectric layer disposed on the gate layer;
a metal layer disposed on the interlayer dielectric layer, wherein the metal layer comprises a plurality of source-drain layers and an auxiliary electrode layer arranged at intervals in the same layer, and the plurality of source-drain layers are connected to the active layer;
a passivation layer disposed on the auxiliary electrode and the plurality of source-drain layers;
a planarization layer disposed on the passivation layer;
a first via hole penetrating the planarization layer and the passivation layer from a side of the planarization layer away from the substrate, and the plurality of source-drain layers are exposed in the first via hole; and
a second via hole penetrating the planarization layer and the passivation layer from the side of the planarization layer away from the substrate, and is spaced apart from the first via hole, and the auxiliary electrode layer is exposed in the fie via hole.

3. The OLED display panel of claim 2, wherein the anode layer comprises a first anode layer and a second anode layer arranged at intervals in the same layer;
the first anode layer is disposed on the planarization layer and connected to the source-drain through the first via hole; and
the second anode layer is disposed on the planarization layer and covers sidewalls of the second via hole, the second anode layer has the undercut opening, and the auxiliary electrode layer is exposed in the undercut opening.

4. The OLED display panel of claim 3, wherein the reflective layer and the third electrode layer comprise a plurality of protrusion portions protruding inward from the sidewalls of the second via hole.

5. The OLED display panel of claim 4, wherein the cathode layer is continuously disposed on the light-emitting layer and the plurality of protruding portions.

6. The OLED display panel of claim 2, wherein the metal layer further comprises a pad layer spaced apart from the plurality of source-drain layers and the auxiliary electrode layer, and an area along a vertical direction of the pad layer is defined as a bonding area.

7. A fabrication method of an OLED display panel, comprising:
providing an array substrate, wherein the array substrate comprises an auxiliary electrode thereon; and
fabricating an anode layer on the array substrate, wherein the step of fabricating the anode layer specifically comprises:
fabricating a first electrode layer on the array substrate;
fabricating a reflective layer on the first electrode layer,
fabricating a third electrode layer on the reflective layer;
fabricating a through hole, wherein the through hole penetrates the first electrode layer and the third electrode layer from a side of the third electrode layer away from the array substrate and extends to a side of the auxiliary electrode away from the array substrate;
fabricating an undercut opening on the first electrode layer, wherein the undercut opening connects the through hole, and the auxiliary electrode is exposed in the undercut opening,
wherein a projection of the through hole on the array substrate falls into a projection of the undercut opening on the array substrate;
fabricating a light-emitting layer on the anode layer, wherein the light-emitting layer is partially disconnected in the undercut opening, and the light-emitting layer covering a portion of the auxiliary electrode layer in the undercut opening; and
fabricating a cathode layer on the light-emitting layer and covering a portion of the auxiliary electrode layer in the undercut opening.

8. The fabrication method of claim 7, wherein a material of the first electrode layer is an indium zinc oxide film, a material of the reflective layer is one or more of molybdenum, titanium, silver alloy, aluminum alloy or molybdenum titanium alloys, and a material of the third electrode is indium tin oxide film.

9. The fabrication method of claim 8, wherein the anode layer is etched by a wet etching process to form the through hole, and the first electrode is etched by an oxalic acid to form the undercut opening.

10. The fabrication method of claim 7, wherein the step of fabricating the light-emitting layer and the cathode layer comprise:
controlling a vapor deposition angle of a vapor deposition source at a first set angle and forming the light-emitting layer on the anode layer by a vapor deposition, wherein the light-emitting layer is disconnected in the undercut opening, and there is a gap is formed between the light-emitting layer on the auxiliary electrode layer and the light-emitting layer on the anode layer; and
adjusting the vapor deposition angle of the vapor deposition source to a second set angle, forming the cathode layer on the light-emitting layer by the vapor deposition and covering a portion of the auxiliary electrode layer in the undercut opening, wherein the cathode layer and the exposed auxiliary electrode layers are in contact with each other.
